(19) United States
(12) Patent Application Publication
(10) Pub. No.: US 2026/0190246 A1
(43) Pub. Date: Jul. 2, 2026

(54) METHOD FOR MANUFACTURING WIRING STRUCTURE

(71) Applicant: Resonac Corporation, Minato-ku, Tokyo (JP)

(72) Inventor: Kei TOGASAKI, Minato-ku, Tokyo (JP)

(21) Appl. No.: 18/857,458

(22) PCT Filed: May 1, 2023
(86) PCT No.: PCT/JP2023/017048

§ 371 Date: Oct. 17, 2024

(51) Int. Cl. H05K 3/18; H05K 3/00; H05K 3/02

(52) U.S. Cl. CPC H05K 3/188; H05K 3/0076; H05K 3/02; H05K 2203/0723

(57) ABSTRACT

A novel method for manufacturing a wiring structure includes: forming a conductor layer by two-stage electrolytic plating on a substrate having a main surface where a first concave portion and a second concave portion are formed, a minimum width of a first bottom surface being larger than a minimum width of a second bottom surface. This method includes: forming a temporary protective layer having a pattern including an opening through which at least a part of a first bottom surface is exposed; forming a first metal plating layer on the first bottom surface; removing the temporary protective layer to expose a second concave portion; and forming a second metal plating layer including a portion configured to fill the second concave portion and a portion provided on the first metal plating layer, thereby forming a conductor layer including the first metal plating layer and the second metal plating layer.

### TECHNICAL FIELD

The present disclosure relates to a method for manufacturing a wiring structure.

### BACKGROUND ART

In an electronic component device including a semiconductor element, a wiring structure including a fine wiring such as a rewiring layer connected to the semiconductor element may be provided. The wiring structure may be formed by a damascene method including forming an electrolytic plating layer in an opening of an insulating layer (for example, Patent Literature 1).

### CITATION LIST

### Patent Literature

Patent Literature 1: International Patent Publication No. 2018/056466

### SUMMARY OF INVENTION

### Technical Problem

A growth rate of a metal plating layer by electrolytic plating tends to be larger in an opening having a narrower width. Therefore, when metal plating layers are collectively formed in a plurality of openings having different widths by electrolytic plating, formulation of the metal plating layers so that the openings having a large width are sufficiently filled easily increases an amount of extra metal plating layers (overburden) protruding from the openings having a narrow width. As a result, after the formation of the metal plating layers, the amount of overburden required to be removed for flattening the metal plating layers or the like may increase.

The present disclosure relates to a method capable of forming metal plating layers while suppressing an amount of overburden required to be removed when a wiring structure is formed by a method including forming metal plating layers in a plurality of openings having different widths by electrolytic plating.

### Solution to Problem

The present disclosure includes the following.

[1] A method for manufacturing a wiring structure, the method including:
preparing a substrate including a main surface where a first concave portion and a second concave portion are formed, the first concave portion including a first bottom surface and a first wall surface, the second concave portion including a second bottom surface and a second wall surface, and a minimum width of the first bottom surface being larger than a minimum width of the second bottom surface;
forming a temporary protective layer on the main surface of the substrate, the temporary protective layer having a pattern including an opening through which at least a part of the first bottom surface is exposed, and comprising a portion blocking the second concave portion;
forming a first metal plating layer on the first bottom surface exposed in the opening;
removing the temporary protective layer to expose the second concave portion;
forming a second metal plating layer comprising a portion filling the second concave portion and a portion provided on the first metal plating layer, thereby forming a conductor layer comprising the first metal plating layer and the second metal plating layer; and
removing a part of the conductor layer, thereby forming a first conductor portion provided in the first concave portion and comprising the first metal plating layer and the second metal plating layer, and a second conductor portion provided in the second concave portion and including the second metal plating layer, wherein
the substrate includes a seed layer having a surface including the first bottom surface and the second bottom surface, and
the first metal plating layer and the second metal plating layer are formed by electrolytic plating.

[2] The method according to [1], wherein the substrate further includes an insulating layer having a pattern including an opening along the first wall surface and an opening along the second wall surface.

[3] The method according to [1] or [2], wherein the first metal plating layer is formed so that a recess is formed in a surface of the first metal plating layer opposite to the first bottom surface.

[4] The method according to any one of [1] to [3], wherein
forming the temporary protective layer includes:
providing a photosensitive resist layer on the main surface of the substrate; and
forming the temporary protective layer having the pattern by patterning the photosensitive resist layer by exposure and development.

[5] The method according to [4], wherein the photosensitive resist layer contains a binder polymer, a photopolymerizable compound having an ethylenically unsaturated bond, and a photopolymerization initiator.

### Advantageous Effects of Invention

When a wiring structure is formed by a method including forming metal plating layers in a plurality of openings having different widths by electrolytic plating, it is possible to form a metal plating layer while suppressing an amount of overburden required to be removed.

### BRIEF DESCRIPTION OF DRAWINGS

FIG. 1 is a process diagram illustrating an example of a method for manufacturing a wiring structure.

FIG. 2 is a process diagram illustrating the example of the method for manufacturing a wiring structure.

FIG. 3 is a process diagram illustrating the example of the method for manufacturing a wiring structure.

### DESCRIPTION OF EMBODIMENTS

The present invention is not limited to the following examples.

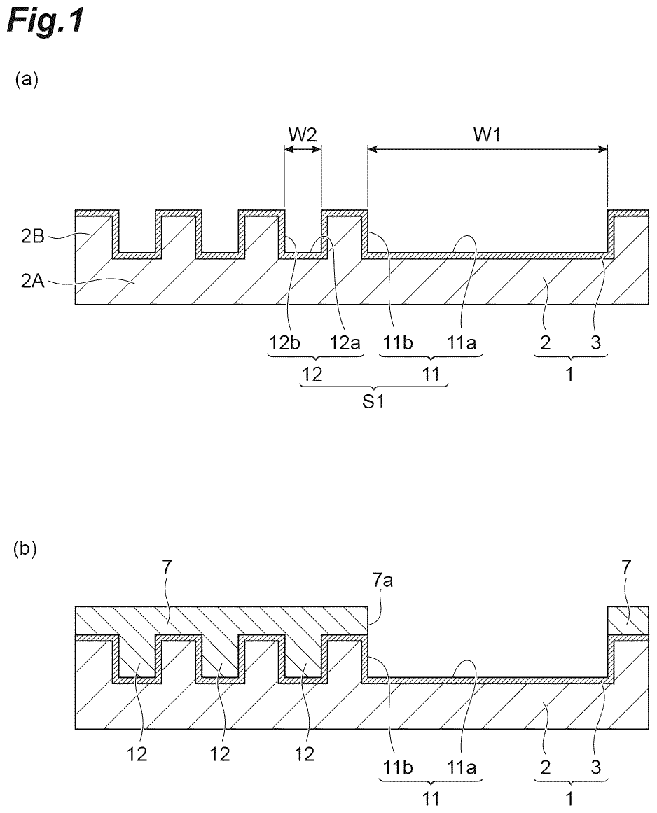

FIGS. 1, 2 and 3 are process diagrams illustrating an example of a method for manufacturing a wiring structure. The method illustrated in FIGS. 1 to 3 includes: preparing a substrate 1 having a main surface S1 where a first concave portion 11 having a first bottom surface 11a and a second concave portion 12 having a second bottom surface 12a are formed; forming a temporary protective layer 7 on the main surface S1 of the substrate 1, the temporary protective layer 7 having a pattern including an opening 7a through which at least a part of the first bottom surface 11a is exposed, and including a portion configured to block the second concave portion 12; forming a first metal plating layer 51 on the first bottom surface 11a exposed in the opening 7a; removing the temporary protective layer 7 to expose the second concave portion 12; forming a second metal plating layer 52 including a portion configured to fill the second concave portion 12 and a portion provided on the first metal plating layer 51, thereby forming a conductor layer 5 including the first metal plating layer 51 and the second metal plating layer 52; and removing a part of the conductor layer 5, thereby forming a first conductor portion 5A provided in the first concave portion 11 and a second conductor portion 5B provided in the second concave portion 12. This method makes it possible to form a wiring structure 50 including a circuit composed of the first conductor portion 5A and the second conductor portion 5B.

The first concave portion 11 formed by the main surface S1 of the substrate 1 has the first bottom surface 11a and the first wall surface 11b surrounding the first bottom surface 11a. The second concave portion 12 formed by the main surface S1 of the substrate 1 has the second bottom surface 12a and the second wall surface 12b surrounding the second bottom surface 12a. A minimum width W1 of the first bottom surface 11a is larger than a minimum width W2 of the second bottom surface 12a. The minimum width of the bottom surface having a longitudinal direction can be a minimum value of a width in a direction perpendicular to the longitudinal direction. Regarding the minimum width of a rectangular or substantially rectangular bottom surface, a length of its short side is regarded as the minimum width.

A ratio W1/W2 of the minimum width of the first bottom surface 11a to the minimum width W2 of the second bottom surface 12a may be 3 or more and 100 or less, 5 or more and 500 or less, or 20 or more and 1000 or less. The minimum width W1 of the first bottom surface 11a may be 10 μm or more and 200 μm or less, 50 μm or more and 500 μm or less, or 20 μm or more and 2000 μm or less. The minimum width W2 of the second bottom surface 12a may be 1 μm or more and 3 μm or less, 0.5 μm or more and 5 μm or less, or 0.3 μm or more and 10 μm or less.

The main surface S1 of the substrate 1 may form three or more concave portions having different minimum widths. In that case, among the plurality of concave portions, when a value of an arbitrary minimum width is set as a reference value, a concave portion having a bottom surface having a minimum width equal to or larger than the reference value can be regarded as a first concave portion, and a concave portion having a bottom surface having a minimum width less than the reference value can be regarded as a second concave portion. The reference value of the minimum width is set in a range of, for example, 0.3 μm or more and 10 μm or less. In this case, the ratio W1/W2 of an average value of the minimum widths W1 to an average value of the minimum widths W2 may be 3 or more and 100 or less, 5 or more and 500 or less, or 20 or more and 1000 or less.

The substrate 1 includes a substrate main body portion 2 and a seed layer 3 provided on the main surface S1 side of the substrate main body portion 2.

The substrate main body portion 2 includes a base body 2A on an inner side relative to positions of the first bottom surface 11a and the second bottom surface 12a, and a plurality of substrate convex portions 2B provided on the base body 2A. The first concave portion 11 and the second concave portion 12 are formed between the adjacent substrate convex portions 2B. A part or all of the base body 2A and the substrate convex portions 2B may be integrally formed, or the substrate convex portions 2B may be provided separately from the base body 2A.

The substrate main body portion 2 or the base body 2A may be a temporary support for forming the wiring structure, or may be a member including a circuit to which the wiring in the wiring structure is connected. The substrate main body portion 2 or the substrate convex portion 2B may be an insulating layer constituting the wiring structure. For example, the substrate 1 may be a member including a semiconductor element, and the wiring structure may be a rewiring layer that is a wiring structure connected to the semiconductor element. In that case, the method according to the present disclosure can be used, for example, for manufacturing a fan-out type semiconductor package having a semiconductor element and a rewiring layer. In addition, the method according to the present disclosure makes it possible also to manufacture an interposer that is a wiring structure configured to connect semiconductor elements in a semiconductor package such as so-called 2.5D, 2.3D, or 2.1D.

A surface of the seed layer 3 opposite to the substrate main body portion 2 includes the first bottom surface 11a and the second bottom surface 12a. In the case of the example illustrated in FIG. 1, the surface of the seed layer 3 further includes the first wall surface 11b and the second wall surface 12b. In other words, the seed layer 3 forms the entire main surface S1. The seed layer 3 is used for forming the first metal plating layer 51 or the second metal plating layer 52 by electrolytic plating. The seed layer 3 can be a layer containing a metal such as copper. A thickness of the seed layer 3 may be, for example, 50 nm or more and 500 nm or less. The seed layer 3 can be formed by, for example, a sputtering method. The seed layer 3 may also be formed by electroless plating.

As illustrated in FIG. 1(b), the temporary protective layer 7 including a portion configured to block the second concave portion 12 is formed on the main surface S1 of the substrate 1. The temporary protective layer 7 has a pattern including an opening 7a through which at least a part of the first bottom surface 11a is exposed. The temporary protective layer 7 may be provided so as to protrude from an end of the first concave portion 11. Although the temporary protective layer 7 illustrated in FIG. 1 fills the second concave portion 12, the temporary protective layer does not necessarily fill the second concave portion completely, and a cavity may be formed between the temporary protective layer 7 and the seed layer 3 in the second concave portion.

The temporary protective layer 7 can be formed by a method including, for example, providing a photosensitive resist layer on the main surface 1S of the substrate 1, and patterning the photosensitive resist layer by exposure and development to form the temporary protective layer 7 having a pattern including the opening 7a. An example of a resist material (photosensitive resin composition) for forming the photosensitive resist layer in this case will be described later.

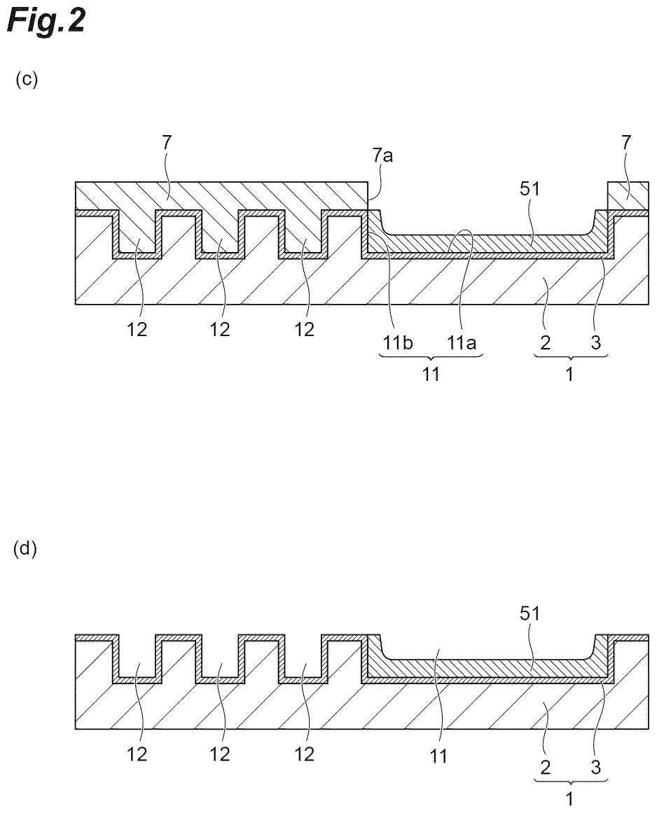

As illustrated in FIG. 2(c), the first metal plating layer 51 is formed by electrolytic plating on the first bottom surface 11a exposed in the opening 7a. The first metal plating layer 51 can be a layer containing copper. The first metal plating layer 51 is formed so that the first concave portion 11 is not completely filled. For example, a ratio of a minimum value of a thickness of the first metal plating layer 51 to a depth of the first concave portion 11 may be 0.2 or more and 0.9 or less. The thickness as used herein means a thickness in a direction perpendicular to the first bottom surface 11a. A recess may be formed in a surface of the first metal plating layer 51 opposite to the first bottom surface 11a. This recess usually has a shape such that the thickness of the first metal plating layer 51 is minimum at a position on a central portion of the first bottom surface 11a.

After the formation of the first metal plating layer 51, the temporary protective layer 7 is removed as illustrated in FIG. 2(d). The removal of the temporary protective layer 7 exposes the second concave portion 12. The temporary protective layer 7 can be removed by, for example, dissolving it in a peeling liquid.

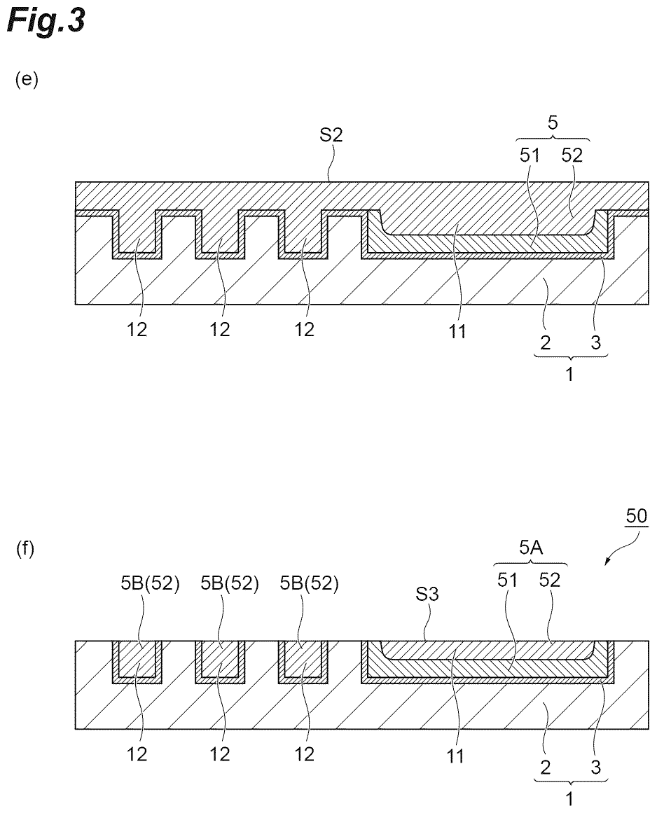

Subsequently, as illustrated in FIG. 3(e), the second metal plating layer 52 is formed by electrolytic plating. The first metal plating layer 51 can also be a layer containing copper. The second metal plating layer 52 includes a portion configured to fill the second concave portion 12, a portion inside the first concave portion 11 provided on the first metal plating layer, and a portion (overburden) protruding from the first concave portion 11 and the second concave portion 12. The conductor layer 5 is composed of the first metal plating layer 51 and the second metal plating layer 52. Since the first metal plating layer 51 is provided in advance, it is possible to form the conductor layer 5 configured to fill the first concave portion 11 and the second concave portion 12 while avoiding formation of an excessive amount of overburden in the vicinity of the second concave portion 12. As a result, it is possible to suppress an amount of the conductor layer 5 required to be removed to form the wiring structure 50 including the first conductor portion 5A and the second conductor portion 5B as illustrated in FIG. 3(f). In addition, even when the amount of overburden is relatively small, a surface S2 of the conductor layer 5 (second metal plating layer 52) opposite to the substrate 1 tends to be flat. The conductor layer 5 having a flat surface is advantageous for efficient removal of the conductor layer 5 by a method such as chemical mechanical polishing.

In the wiring structure 50 formed by removing a part of the conductor layer 5, the first conductor portion 5A includes the first metal plating layer 51 and the second metal plating layer 52, and the second conductor portion 5B includes the second metal plating layer 52. In the case of the example illustrated in FIG. 3, a part of the seed layer 3 is also removed, and a flat main surface S3 is formed by the first conductor portion 5A, the second conductor portion 5B, and the substrate 1 (or the substrate main body portion 2). The first conductor portion 5A having a wide width can be, for example, a land or a via. The second conductor portion 5B having a narrow width can be, for example, a wiring having a linearly extending portion. A wiring structure having a multilayer structure may be formed by forming an additional wiring layer on a wiring layer including the first conductor portion 5A and the second conductor portion 5B.

The method of the present disclosure is not limited to the above example, and can be changed as necessary. For example, the substrate 1 may include a base body having a flat surface along a surface including the first bottom surface 11a and the second bottom surface 12a, and a substrate convex portion provided on the flat surface side of the base body, and the substrate convex portion may be a resist layer. The resist layer (substrate convex portion 2B) in this case has a pattern including an opening along the first wall surface 11b and an opening along the second wall surface 12b. After the formation of the first conductor portion 5A and the second conductor portion 5B, the resist layer (substrate convex portion 2B) may be removed.

The photosensitive resist layer for forming the temporary protective layer 7 having a predetermined pattern can be, for example, a layer formed of a photosensitive resin composition containing a binder polymer, a photopolymerizable compound having an ethylenically unsaturated bond, and a photopolymerization initiator.

The binder polymer may be, for example, a copolymer containing benzyl (meth)acrylate or a derivative thereof, styrene or a styrene derivative, a (meth)acrylic acid alkyl ester, and (meth)acrylic acid as monomer units.

Specific examples of the benzyl (meth)acrylate derivative constituting the binder polymer include 4-methylbenzyl (meth)acrylate, 4-ethylbenzyl (meth)acrylate, 4-tert-butylbenzyl (meth)acrylate, 4-methoxybenzyl (meth)acrylate, 4-ethoxybenzyl (meth)acrylate, 4-hydroxylbenzyl (meth)acrylate, and 4-chlorobenzyl (meth)acrylate.

Specific examples of the styrene derivative constituting the binder polymer include vinyltoluene, p-methylstyrene, and p-chlorostyrene.

The (meth)acrylic acid alkyl ester constituting the binder polymer may be an ester compound formed of (meth)acrylic acid and a linear or branched aliphatic alcohol having 1 to 12 carbon atoms. The aliphatic alcohol may have 1 to 8 or 1 to 4 carbon atoms. Specific examples of the (meth)acrylic acid alkyl ester include methyl (meth)acrylate, ethyl (meth)acrylate, propyl (meth)acrylate, isopropyl (meth)acrylate, butyl (meth)acrylate, tert-butyl (meth)acrylate, pentyl (meth)acrylate, hexyl (meth)acrylate, heptyl (meth)acrylate, octyl (meth)acrylate, and 2-ethylhexyl (meth)acrylate.

A proportion of the monomer unit derived from benzyl (meth)acrylate or a derivative thereof in the binder polymer may be 50 to 80 mass %, 50 to 75 mass %, 50 to 70 mass %, or 50 to 65 mass % based on a mass of the binder polymer. A proportion of the monomer unit derived from styrene or a styrene derivative in the binder polymer may be 5 to 40 mass % or 5 to 35 mass % based on the mass of the binder polymer. A proportion of the monomer unit derived from a (meth)acrylic acid alkyl ester in the binder polymer may be 1 to 20 mass %, 1 to 15 mass %, 1 to 10 mass %, or 1 to 5 mass % based on the mass of the binder polymer. A proportion of the monomer unit derived from (meth)acrylic acid in the binder polymer may be 5 to 30 mass %, 5 to 25 mass %, or 10 to 25 mass % based on the mass of the binder polymer.

A weight average molecular weight (Mw) of the binder polymer may be 20000 to 150000, 30000 to 100000, 40000 to 80000, or 40000 to 60000. The weight average molecular weight as used herein means a value in terms of standard polystyrene as determined by gel permeation chromatography (GPC).

An acid value (mgKOH/g) of the binder polymer may be 13 to 78, 39 to 65, or 52 to 62. The acid value as used herein means an amount (mg) of potassium hydroxide required for neutralization of 1 g of the binder polymer.

Specific examples of the photopolymerizable compound having an ethylenically unsaturated bond include bisphenol A-based (meth)acrylate compounds, hydrogenated bisphenol A-based (meth)acrylate compounds, polyalkylene glycol (meth)acrylates, urethane monomers, pentaerythritol (meth)acrylates, and trimethylolpropane (meth)acrylates. These are used singly, or two or more thereof are used in combination. A bisphenol A-based di(meth)acrylate compound may be, for example, a compound represented by the following general formula (1).

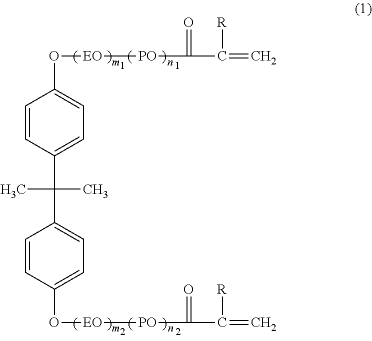

In Formula (1), Rs each independently represent a hydrogen atom or a methyl group. EO and PO represent an oxyethylene group and an oxypropylene group, respectively. m₁, m₂, n₁, and n₂ each independently represent 0 to 40, m₁+m₂ represents 1 to 40, and n₁+n₂ represents 0 to 20. Either EO or PO may be present on a phenolic hydroxyl group side. m₁, m₂, n₁, and n₂ each represent a number of EOs or POs. A compound in which m₁+m₂ is 5 or less on average and a compound in which m₁+m₂ is 6 to 40 on average may be combined.

The polyalkylene glycol (meth)acrylate may be a compound represented by the following formula (2). As the photopolymerizable compound having an ethylenically unsaturated bond, a bisphenol A-based di(meth)acrylate compound and a compound represented by the following formula (2) may be combined.

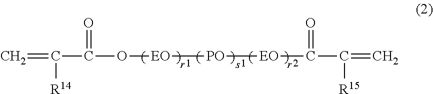

In Formula (2), R¹⁴ and R¹⁵ each independently represent a hydrogen atom or a methyl group, EO and PO have the same meaning as described above, s¹ represents 1 to 30, r¹ and r² each represent 0 to 30, and r¹+r² represents 1 to 30. Examples of commercially available products of the compound represented by Formula (2) include vinyl compounds (trade name: FA-023M, manufactured by Hitachi Chemical Company, Ltd.) in which R¹⁴ and R¹⁵ are methyl groups, r¹+r²=4 (average value), and s¹=12 (average value).

Specific examples of the photopolymerization initiator include aromatic ketones such as benzophenone, N,N′-tetramethyl-4,4′-diaminobenzophenone (Michler's ketone), N,N′-tetraethyl-4,4′-diaminobenzophenone, 4-methoxy-4′-dimethylaminobenzophenone, 2-benzyl-2-dimethylamino-1-(4-morpholinophenyl)-butanone-1, and 2-methyl-1-[4-(methylthio)phenyl]-2 morpholino-propanone-1; quinones such as 2-ethylanthraquinone, phenanthrenequinone, 2-tert-butylanthraquinone, octamethylanthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-naphthoquinone, 9,10 phenanthraquinone, 2-methyl 1,4-naphthoquinone, and 2,3-dimethylanthraquinone; benzoin ether compounds such as benzoin methyl ether, benzoin ethyl ether, and benzoin phenyl ether, and benzoin compounds such as benzoin, methylbenzoin, and ethylbenzoin; benzyl derivatives such as benzyl dimethyl ketal, and 2,4,5-triarylimidazole dimers such as 2-(o-chlorophenyl)-4,5-diphenylimidazole dimer, 2-(o-chlorophenyl)-4,5-di(methoxyphenyl) imidazole dimer, 2-(o-fluorophenyl)-4,5-diphenylimidazole dimer, 2-(o-methoxyphenyl)-4,5-diphenylimidazole dimer, and 2-(p-methoxyphenyl)-4,5-diphenylimidazole dimer; acridine derivatives such as 9-phenylacridine and 1,7-bis(9,9′-acridinyl) heptane; N-phenylglycine; N-phenylglycine derivatives; and coumarin-based compounds. These are used singly, or two or more thereof are used in combination. The photopolymerization initiator may contain a 2,4,5-triarylimidazole dimer, particularly a 2-(O-chlorophenyl)-4,5-diphenylimidazole dimer.

A content of the binder polymer in the photosensitive resin composition may be 40 to 80 parts by mass, 45 to 75 parts by mass, or 50 to 70 parts by mass with respect to 100 parts by mass of a total amount of the binder polymer and the photopolymerizable compound. A content of the photopolymerization initiator in the photosensitive resin composition may be 0.01 to 5 parts by mass, 0.1 to 4.5 parts by mass, or 1 to 4 parts by mass with respect to 100 parts by mass of the total amount of the binder polymer and the photopolymerizable compound.

The photosensitive resin composition may contain other components as necessary. Examples of such other components include a photopolymerizable compound having a cationically polymerizable cyclic ether group, a cationic polymerization initiator, a sensitizer, a dye such as Malachite Green, photochromogenic agents such as tribromomethylphenyl sulfone and Leuco Crystal Violet, a thermal coloring inhibitor, a plasticizer such as p-toluenesulfonamide, a pigment, a filler, an antifoaming agent, a flame retardant, a stabilizer, an adhesion imparting agent, a leveling agent, a peeling accelerator, an antioxidant, a fragrance, an imaging agent, and a thermal crosslinking agent. A content of each of such other components may be about 0.01 to 20 parts by mass with respect to 100 parts by mass of the total amount of the binder polymer and the photopolymerizable compound.

A total content of the binder polymer, the photopolymerizable compound, and the photopolymerization initiator in the photosensitive resin composition may be 90 to 100 mass % or 95 to 100 mass % with respect to a total mass of components other than the solvent in the photosensitive resin composition.

In order to form a photosensitive resist layer, a resist film containing a photosensitive resin composition may be laminated on the main surface S1 of the substrate 1, or a photosensitive resin composition containing a solvent may be applied to the main surface S1 of the substrate 1, and the solvent may be removed from the coating film.

### REFERENCE SIGNS LIST

1 Substrate
2 Substrate main body portion
3 Seed layer
5 Conductor layer
5A First conductor portion
5B Second conductor portion
7 Temporary protective layer
7a Opening
11 First concave portion
11a First bottom surface
11b First wall surface
12 Second concave portion
12a Second bottom surface
12b Second wall surface
50 Wiring structure
51 First metal plating layer
52 Second metal plating layer
W1 Minimum width of first bottom surface
W2 Minimum width of second bottom surface

1. A method for manufacturing a wiring structure, the method comprising:
preparing a substrate including a main surface where a first concave portion and a second concave portion are formed, the first concave portion including a first bottom surface and a first wall surface, the second concave portion including a second bottom surface and a second wall surface, and a minimum width of the first bottom surface being larger than a minimum width of the second bottom surface;
forming a temporary protective layer on the main surface of the substrate, the temporary protective layer having a pattern including an opening through which at least a part of the first bottom surface is exposed, and comprising a portion blocking the second concave portion;
forming a first metal plating layer on the first bottom surface exposed in the opening;
removing the temporary protective layer to expose the second concave portion;
forming a second metal plating layer comprising a portion filing the second concave portion and a portion provided on the first metal plating layer, thereby forming a conductor layer comprising the first metal plating layer and the second metal plating layer; and
removing a part of the conductor layer, thereby forming a first conductor portion provided in the first concave portion and comprising the first metal plating layer and the second metal plating layer, and a second conductor portion provided in the second concave portion and comprising the second metal plating layer, wherein
the substrate comprises a seed layer having a surface including the first bottom surface and the second bottom surface, and
the first metal plating layer and the second metal plating layer are formed by electrolytic plating.

2. The method according to claim 1, wherein the substrate further includes an insulating layer having a pattern including an opening along the first wall surface and an opening along the second wall surface.

3. The method according to claim 1, wherein the first metal plating layer is formed so that a recess is formed in a surface of the first metal plating layer opposite to the first bottom surface.

4. The method according to claim 1, wherein
forming the temporary protective layer includes:
providing a photosensitive resist layer on the main surface of the substrate; and
forming the temporary protective layer having the pattern by patterning the photosensitive resist layer by exposure and development.

5. The method according to claim 4, wherein the photosensitive resist layer contains a binder polymer, a photopolymerizable compound having an ethylenically unsaturated bond, and a photopolymerization initiator.
